(19) United States
(12) Patent Application Publication
(10) Pub. No.: US 2024/0072547 A1
(43) Pub. Date: Feb. 29, 2024

(54) BATTERY BALANCING SYSTEM AND OPERATION METHOD THEREOF

(71) Applicant: ELECTRONICS AND TELECOMMUNICATIONS RESEARCH INSTITUTE, Daejeon (KR)

(72) Inventors: Yil Suk YANG, Daejeon (KR); Chi Hoon JUN, Daejeon (KR)

(21) Appl. No.: 18/364,210

(22) Filed: Aug. 2, 2023

(30) Foreign Application Priority Data
Aug. 26, 2022 (KR) 10-2022-0107924

(51) Int. Cl. H02J 7/00

(52) U.S. Cl. CPC H02J 7/0019; H02J 7/0048

(57) ABSTRACT

Disclosed is a battery balancing system, which includes a battery pack block including a first battery module and a second battery module arranged in a first row and a third battery module and a fourth battery module arranged in a second row, a balancing control block including first control circuits respectively connected to the first battery module and the second battery module in the first row and second control circuits respectively connected to the third battery module and the fourth battery module in the second row, a battery state determination block that receives output signals from the first control circuits and the second control circuits to determine states of the first to fourth battery modules, and a controller that applies a first row selection signal to the first control circuits and applies a second row selection signal to the second control circuits.

### CROSS-REFERENCE TO RELATED APPLICATIONS

This application claims priority under 35 U.S.C. § 119 to Korean Patent Application No. 10-2022-0107924, filed on Aug. 26, 2022, in the Korean Intellectual Property Office, the disclosures of which are incorporated by reference herein in their entireties.

### BACKGROUND

Embodiments of the present disclosure described herein relate to a battery balancing system and an operation method thereof, and more particularly, relate to a system and method for performing state measurement and balancing of battery modules in parallel.

In a battery pack composed of series and parallel combinations of battery modules in which a plurality of cells are connected in series, a balancing function that monitors voltage, current, and temperature between the battery modules or cells and compensates for voltage, current, and temperature deviations between the battery modules or cells is particularly important in a battery pack system.

Balancing methods mainly used in current battery packs include a passive balancing method and an active balancing method.

### SUMMARY

Embodiments of the present disclosure provide a battery balancing system capable of reducing the time required to perform battery balancing.

According to an embodiment of the present disclosure, a battery balancing system includes a battery pack block including a first battery module and a second battery module arranged in a first row and a third battery module and a fourth battery module arranged in a second row, a balancing control block including first control circuits respectively connected to the first battery module and the second battery module in the first row and second control circuits respectively connected to the third battery module and the fourth battery module in the second row, a battery state determination block that receives output signals from the first control circuits and the second control circuits to determine states of the first to fourth battery modules, and a controller that applies a first row selection signal to the first control circuits and applies a second row selection signal to the second control circuits, and, when the first row selection signal is activated, the battery state determination block determines states of the first and second battery modules in the first row and outputs a determination result, and the controller performs balancing with respect to the first and second battery modules of the first row or activates the second row selection signal, based on the determination result.

According to an embodiment, the battery balancing system may further include a balancing block including balancing modules respectively connected to the first control circuits and the second control circuits, and each of the first control circuits and the second control circuits may connect a battery module and a balancing module connected thereto or may output an output of the battery module as the output signal, based on an output selection signal, and the controller may control the output selection signal based on the determination result.

According to an embodiment, each of the first control circuits may include a multiplexer that outputs an output of the battery module connected to the first control circuit as a first output or a second output based on the output selection signal, and a switch including a first gate terminal to which the first row selection signal is applied, a first source/drain connected to the second output, and a second source/drain to output the output signal, and the first output may be connected to the balancing module connected to the first control circuit.

According to an embodiment, the controller may be configured to, when the determination result is abnormal, perform balancing with respect to an abnormal battery module by outputting an output of the abnormal battery module as the first output, by controlling the output selection signal, and when the determination result is normal, deactivate the first row selection signal and activate the second row selection signal.

According to an embodiment, the first battery module and the third battery module may be arranged in a first column, and the second battery module and the fourth battery module are arranged in a second column, the first control circuit connected to the first battery module and the second control circuit connected to the third battery module may transfer the output signal through a first output line corresponding to the first column, the first control circuit connected to the second battery module and the second control circuit connected to the fourth battery module may transfer the output signal through a second output line corresponding to the second column, and the battery state determination block may include a first determination block connected to the first output line and a second determination block connected to the second output line.

According to an embodiment, the first determination block may be configured to compare an output signal received through the first output line with reference state information to determine a state of the first battery module in the first column and to output the determination result, and the second determination block may be configured to compare an output signal received through the second output line with reference state information to determine a state of the second battery module in the second column and to output the determination result.

According to an embodiment, when at least one of the first determination block and the second determination block outputs the determination result determined to be the abnormal, the controller may perform balancing with respect to the battery module determined to be the abnormal among the first battery module and the second battery module, and when both the first determination block and the second determination block output the determination result determined to be the normal, the controller may activate the second row selection signal.

According to an embodiment, the first determination block may include a multiplexer that selects and outputs the reference state information, a comparator that compares the output signal received through the first output line with the selected reference state information to generate a comparison result, and a determination unit that determines the state of the first battery module based on the comparison result to output the determination result.

According to an embodiment, the reference state information may include a reference voltage, a reference current, and a reference temperature, and the multiplexer may select and output any one of the reference voltage, the reference current, and the reference temperature based on a reference state selection signal.

According to an embodiment, the battery balancing system may further include a balancing block including balancing modules respectively connected to the first control circuits and the second control circuits, and each of the first control circuits and the second control circuits may connect a battery module and a balancing module connected thereto or may output an output of the battery module as the output signal, based on an output selection signal, and the controller may generate the output selection signal based on the determination result.

According to an embodiment of the present disclosure, a method of operating a battery balancing system including a first battery module and a second battery module arranged in a first row and respectively connected to first control circuits, and a third battery module and a fourth battery module arranged in a second row and respectively connected to second control circuits, includes activating a first row selection signal applied to the first control circuits, receiving output signals of the first and second battery modules from the first control circuits, comparing the output signal with reference state information to determine whether the first and second battery modules are normal and outputting a determination result, and performing balancing with respect to the first and second battery modules based on the determination result or activating a second row selection signal applied to the second control circuits.

According to an embodiment, the first control circuits and the second control circuits may respectively connect a battery module and a balancing module connected thereto or may respectively output an output of the battery module as the output signal, based on an output selection signal.

According to an embodiment, each of the first control circuits may include a multiplexer that outputs an output of the battery module connected to the first control circuit as a first output or a second output based on the output selection signal, and a switch including a first gate terminal to which the first row selection signal is applied, a first source/drain connected to the second output, and a second source/drain to output the output signal, and the first output may be connected to the balancing module connected to the first control circuit.

According to an embodiment, when the determination result is abnormal, balancing with respect to an abnormal battery module may be performed by outputting an output of the abnormal battery module as the first output, by controlling the output selection signal, and when the determination result is normal, the first row selection signal may be deactivated and the second row selection signal may be activated.

According to an embodiment, in the receiving of the output signal, the first battery module and the third battery module may be arranged in a first column, and the second battery module and the fourth battery module may be arranged in a second column, the first control circuit connected to the first battery module and the second control circuit connected to the third battery module may receive the output signal through a first output line corresponding to the first column, and the first control circuit connected to the second battery module and the second control circuit connected to the fourth battery module may receive the output signal through a second output line corresponding to the second column.

According to an embodiment, the outputting of the determination result may include comparing an output signal received through the first output line with the reference state information to determine a state of the first battery module in the first column and to output the determination result, and comparing an output signal received through the second output line with the reference state information to determine a state of the second battery module in the second column and to output the determination result.

According to an embodiment, when at least one of the first battery module and the second battery module is determined to be abnormal, balancing with respect to the battery module determined to be the abnormal among the first battery module and the second battery module may be performed, and when both the first battery module and the second battery module are determined to be normal, the second row selection signal may be activated.

According to an embodiment, the outputting of the determination result may include outputting the determination result from a first determination block connected to the first output line, and the first determination block may include a multiplexer that selects and outputs the reference state information, a comparator that compares the output signal received through the first output line with the selected reference state information to generate a comparison result, and a determination unit that determines the state of the first battery module based on the comparison result to output the determination result.

According to an embodiment, the reference state information may include a reference voltage, a reference current, and a reference temperature, and the multiplexer may select and output any one of the reference voltage, the reference current, and the reference temperature based on a reference state selection signal.

### BRIEF DESCRIPTION OF THE FIGURES

A detailed description of each drawing is provided to facilitate a more thorough understanding of the drawings referenced in the detailed description of the present disclosure.

FIG. 1 is a block diagram illustrating an embodiment of a battery balancing system, according to the present disclosure.

FIG. 2 is a diagram illustrating an example for describing a battery balancing system of FIG. 1.

FIG. 3 is a flowchart illustrating an operation method of a battery balancing system of FIG. 1.

FIG. 4 is a timing diagram for describing an operation of a battery balancing system of FIG. 1.

### DETAILED DESCRIPTION

Hereinafter, embodiments of the present disclosure will be described clearly and in detail such that those skilled in the art may easily carry out the present disclosure.

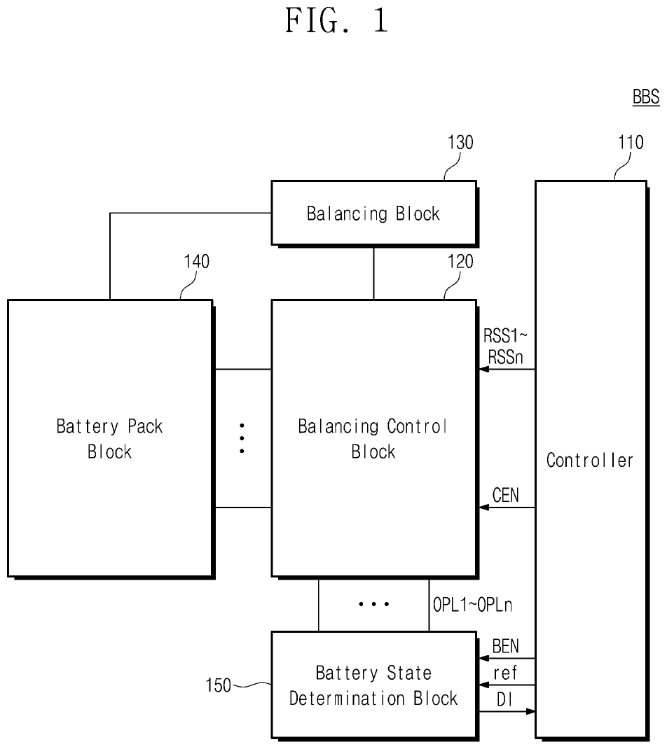

FIG. 1 is a block diagram illustrating an embodiment of a battery balancing system, according to the present disclosure.

Referring to FIG. 1, an embodiment of a battery balancing system BBS according to the present disclosure may include a controller 110, a balancing control block 120, a balancing block 130, a battery pack block 140, and a battery state determination block 150. The battery balancing system BBS may be configured to determine the state of the battery pack block 140 and perform balancing on the battery pack block 140 based on a determination result DI.

The battery pack block 140 may include battery modules arranged in a matrix form. The battery pack block 140 may include M×N battery modules arranged in ‘M’ rows and ‘N’ columns. The M×N number of battery modules may be connected in series to output voltage, or connected in parallel to output current.

Each row may include ‘N’ battery modules. For example, the number of battery modules included in each of first to M-th rows is ‘N’, which may be the same as each other.

However, it is not limited thereto, and a plurality of battery modules may be included in the battery pack block 140 and the arrangement of the battery modules may also vary. For example, the number of battery modules included in each of the ‘M’ rows of the battery pack block 140 may be different from each other. Hereinafter, for convenience of understanding, it is assumed that the battery pack block 140 is composed of battery modules arranged in ‘M’ rows and ‘N’ columns.

The balancing block 130 may be configured to perform balancing on the battery pack block 140. For example, the balancing may mean adjusting the charge amount of a specific battery module.

In an embodiment, when the output voltage of a specific battery module differs from a reference value by a predetermined level or more, balancing of the battery module may be performed. When the amount of output current of a specific battery module is different from the reference value by more than a specific amount, or when the surface temperature of the specific battery module is different from a reference value by more than a specific value, balancing of the battery modules may be performed.

In another embodiment, when the charge amount of a specific battery module is different from the charge amount of adjacent battery modules by a predetermined reference or more, balancing of the battery module may be performed. When the amount of output current of a specific battery module is different from the amount of output current of the adjacent battery module by a predetermined reference or more, or when the surface temperature of a specific battery module is different from the surface temperature of the adjacent battery module by a preset reference or more, balancing of the battery module may be performed.

The balancing block 130 may include a plurality balancing modules. The number of balancing modules may be the same as the number of battery modules of the battery pack block 140. For example, when the battery pack block 140 includes M×N battery modules, the balancing block 130 may also include M×N balancing modules arranged in ‘M’ rows and ‘N’ columns.

Each of the balancing modules may correspond to the battery module on a one-to-one basis. For example, the ‘N’ number of first balancing modules in a first row R1 may be connected to the ‘N’ number of battery modules in the first row R1, respectively, the ‘N’ number of second balancing modules in a second row may be connected to the ‘N’ number of battery modules in the second row, respectively, and the ‘N’ number of M-th balancing modules in a M-th row may be connected to the ‘N’ number of battery modules in the M-th row, respectively.

The balancing control block 120 may be configured to output an output signal including state information on the battery modules of the battery pack block 140 or perform balancing by connecting the battery modules to the balancing modules.

The balancing control block 120 may include control circuits connected to each of the battery modules of the battery pack block 140. For example, when the battery pack block 140 includes M×N number of battery modules, the balancing control block 120 may also include M×N number of control circuits arranged in ‘M’ rows and ‘N’ columns. Each control circuit may output the output of the battery module connected thereto as an output signal.

The control circuits may also be connected with the balancing modules. The control circuit may allow balancing with respect to the battery module to be performed by connecting a terminal of the battery module to a terminal of the balancing module.

Each of the control circuits may correspond to the battery module and the balancing module on a one-to-one basis. For example, the ‘N’ number of first control circuits in the first row may be connected to the ‘N’ number of battery modules and the ‘N’ number of first balancing modules in the first row, respectively, the ‘N’ number of second control circuits in the second row may be connected to the ‘N’ number of battery modules and the ‘N’ number of second balancing modules 130-2 in the second row, respectively, and the ‘N’ number of M-th control circuits in the M-th row may be connected to the ‘N’ number of battery modules and the ‘N’ number of the M-th balancing modules in the M-th row, respectively.

The control circuits of the balancing control block 120 may be connected to output lines OPL1 to OPLn. The output lines OPL1 to OPLn may transfer output signals output from the control circuits to the battery state determination block 150. The number of output lines OPL1 to OPLn may be the same as the number of columns of the control circuits. For example, first to N-th output lines OPL1 to OPLn corresponding to first to N-th columns may be provided.

The control circuits included in the same column may be commonly connected to the same output line. For example, the first output line may be connected to control circuits disposed in a first column among control circuits of first to M-th rows. The second output line may be connected to control circuits disposed in a second column among the control circuits in the first to M-th rows. The N-th output line may be connected to control circuits disposed in an N-th column among the control circuits in the first to M-th rows.

The battery state determination block 150 may be connected to the output lines OPL1 to OPLn. The battery state determination block 150 may be configured to determine states of the battery modules based on output signals transferred from the control circuits and to output the determination result DI to the controller.

The battery state determination block 150 may include determination blocks connected to the output lines OPL1 to OPLn. The number of determination blocks may be the same as the number of output lines OPL1 to OPLn. Each determination block may receive an output signal from an output line, may determine a state of a battery module connected to the control circuit, and may output the determination result DI.

For example, the first determination block may be connected to the first output line to determine states of the battery modules in the first column. The second determination block may be connected to the second output line to determine states of the battery modules in the second column. The N-th determination block may be connected to the N-th output line to determine states of the battery modules in the N-th column.

Each determination block may compare the output signal with the reference state information ‘ref’ and may determine whether the battery module is normal based on the comparison result. The reference state information ref may include information on a reference voltage, a reference current, and a reference temperature. The output signal may include information on the output voltage, output current, and surface temperature of the battery module.

For example, each determination block may determine whether the battery module is normal by comparing the output voltage of the output signal with the reference voltage. Each determination block may compare the output current of the output signal with a reference current or may compare the surface temperature of the output signal with a reference temperature to determine whether the battery module is normal.

However, without being limited to the above description, the battery state determination block 150 may determine the battery state in a different way based on the output signal received from the control circuit.

The controller 110 may be configured to control the balancing control block 120 based on various signals. The controller 110 may generate a first row selection signal, and may generate a row selection signal and an output selection signal CEN based on the determination result DI received from the battery state determination block 150.

Row selection signals RSS1 to RSSN may be signals for selecting at least one of the control circuits in the first to M-th rows. For example, the first row selection signal is a signal for selecting first control circuits in the first row, the second row selection signal is a signal for selecting second control circuits in the second row, and the M-th row selection signal is a signal for selecting the M-th control circuits of the M-th row.

The control circuits of the balancing control block 120 may receive the row selection signals RSS1 to RSSN. For example, the first control circuits connected to the ‘N’ number of battery modules in the first row may receive the first row selection signal, the second control circuits connected to the ‘N’ number of battery modules in the second row may receive the second row selection signal, and the M-th control circuits connected to the ‘N’ number of battery modules in the M-th row may receive the M-th row selection signal.

The output selection signal CEN may be a signal for the control circuit to output an output signal from the battery module connected thereto or to connect the battery module to the balancing module.

The control circuits of the balancing control block 120 may receive the output selection signal CEN. Each control circuit may be configured to output the output data of the battery module or to connect the battery module to the balancing module based on the output selection signal CEN.

When the control circuits of a specific row are selected by the row selection signal, the control circuits may output the output signals from balancing modules connected thereto to the output line. The battery state determination block 150 may determine states of battery modules in a specific row based on output signals transferred from output lines.

The controller 110 may provide the reference state information ref and a reference state selection signal BEN to the battery state determination block 150. The battery state determination block 150 may determine whether to perform balancing by comparing an output signal provided from an output line with the reference state information ref.

The controller 110 may receive the determination result DI from the battery state determination block 150. Based on the determination result DI, the controller 110 may perform balancing of battery modules in a specific row or generate a row selection signal and the output selection signal CEN for a subsequent row.

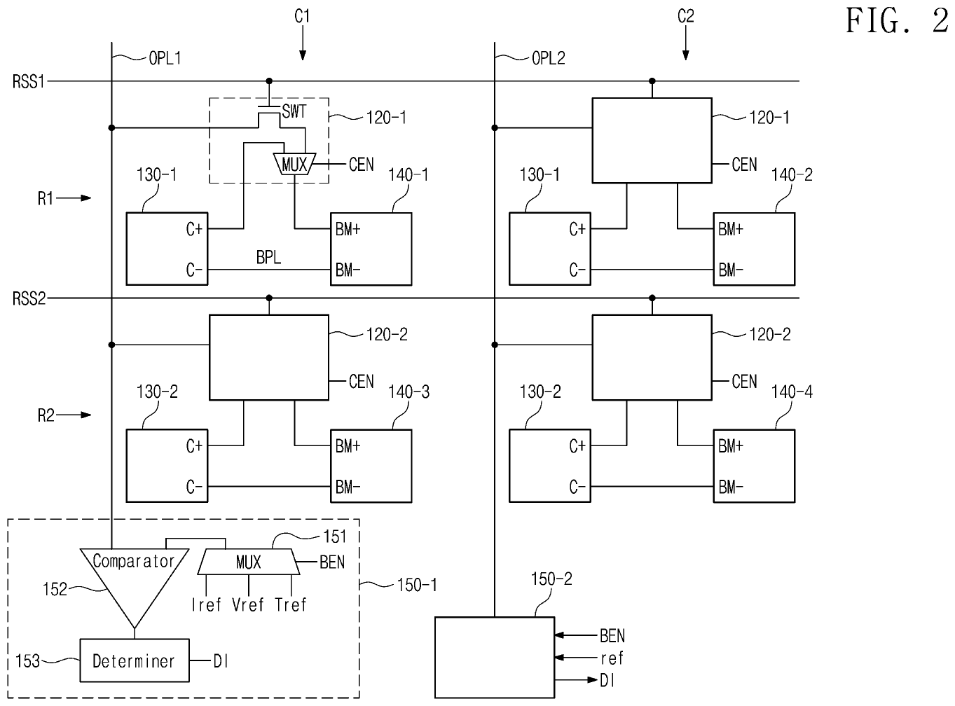

Hereinafter, operations of the controller 110, the balancing control block 120, and the battery state determination block 150 will be described in detail with reference to FIG. 2.

FIG. 2 is a diagram illustrating an example for describing a battery balancing system of FIG. 1. For convenience of description, the battery balancing system BBS describes the operation of battery modules, balancing modules, control circuits, and determination blocks, which are arranged in two rows and two columns.

Referring to FIG. 2, in the first row R1, first control circuits 120-1, first balancing modules 130-1, a first battery module 140-1, and a second battery module 140-2 may be disposed. The first battery module 140-1 may be disposed in the first row R1 and a first column C1, and the second battery module 140-2 may be disposed in the first row R1 and a second column C2.

In a second row R2, second control circuits 120-2, second balancing modules 130-2, a third battery module 140-3, and a fourth battery module 140-4 may be disposed. The third battery module 140-3 may be disposed in the second row R2 and the first column C1, and the fourth battery module 140-4 may be disposed in the second row R2 and the second column C2.

The first row selection signal RSS1 may be applied to the first control circuits 120-1 disposed in the first row R1, and the second row selection signal RSS2 may be applied to the second control circuits 120-2 disposed in the second row R2.

The first control circuit 120-1 and the second control circuit 120-2 disposed in the first column C1 may be connected to the first output line OPL1, and the first control circuit 120-1 and the second control circuit 120-2 disposed in the second column C2 may be connected to the second output line OPL2. The first output line OPL1 may be connected to a first determination module 150-1, and the second output line OPL2 may be connected to a second determination module 150-2.

The first control circuits 120-1 and the second control circuits 120-2 may be configured to perform actually the same operation. In detail, the configuration of the control circuits may be actually the same. Hereinafter, the first control circuit 120-1 in the first row R1 and first column C1 will be described as a representative example.

The control circuit 120-1 may include a switch SWT and a multiplexer MUX.

The switch SWT may be switched on or switched off based on the row selection signal. When the switch SWT is in a switched-on state, the control circuit may output an output signal.

The switch SWT may include a transistor including a gate terminal, a first source/drain, and a second source/drain. The row selection signal may be applied to the gate terminal. The first source/drain may be connected to the multiplexer MUX, and the second source/drain may be connected to an output line.

When the row selection signal applied to the gate terminal is activated, the switch SWT may output a signal input to the first source/drain to the second source/drain. When the row selection signal applied to the gate terminal is inactivated, the switch SWT is switched off and the control circuit may not generate an output signal.

The multiplexer MUX may receive the output selection signal CEN and may output a signal input from the battery module 140-1 as a first output or a second output. The first output of the multiplexer MUX may be connected to a + terminal BM+ of the battery module 140-1, and the second output of the multiplexer MUX may be connected to the first source/drain of the switch SWT.

In an embodiment, when the output selection signal CEN is a first signal (e.g., ‘0’ signal), the multiplexer MUX may output the signal output from the + terminal BM+ of the battery module 140-1 as the first output. The + terminal BM+ of the battery module 140-1 may be connected to a + terminal C+ of the balancing module 130-1, and a − terminal BM− of the battery module 140-1 may be connected to a − terminal C− of the balancing module 130-1. The balancing module 130-1 may perform balancing on the connected battery module 140-1.

In an embodiment, when the output selection signal CEN is a second signal (e.g., ‘1’ signal), the multiplexer MUX may output the signal output from the + terminal BM+ of the battery module 140-1 as the second output. When the row selection signal applied to the switch SWT is activated and the switch SWT is in a switched-on state, the control circuit may output the second output input to the first source/drain as the output signal.

The determination module may receive the output signal from the output line. The first determination module 150-1 may receive an output signal from the control circuit of the first column C1, and the second determination module 150-2 may receive an output signal from the control circuit of the second column C2.

The first determination module 150-1 and the second determination module 150-2 may be configured to perform actually the same operation. In detail, configurations of the determination modules may be actually the same. Hereinafter, the first determination module 150-1 connected to the second output line OPL2 of the first row R1 will be described as a representative example.

The determination module may include a multiplexer 151, a comparator 152, and a determiner 153.

The multiplexer 151 may output one of the reference state information in response to the reference state selection signal BEN. Among the reference state information, a reference voltage Vref may be provided as a first input of the multiplexer 151, a reference current Iref may be provided as a second input of the multiplexer 151, and a reference temperature Tref may be provided as a third input of the multiplexer 151.

When the reference state selection signal BEN has a first value, the multiplexer 151 may output the first input. When the reference state selection signal BEN has a second value, the multiplexer 151 may output the second input. When the reference state selection signal BEN has a third value, the multiplexer 151 may output the third input. The output of the multiplexer 151 may be input to the comparator 152.

The comparator 152 may compare the output signal received from the output line with reference state information output from the multiplexer 151. For example, when the reference state selection signal BEN has the first value, the comparator 152 may compare the output voltage of the battery module with the reference voltage Vref. When the reference state selection signal BEN has the second value, the comparator 152 may compare the output current of the battery module with the reference current Iref. When the reference state selection signal BEN has the third value, the comparator 152 may compare the surface temperature of the battery module with the reference temperature Tref.

The comparator 152 may output a comparison result and may provide the comparison result to the determiner 153.

The determiner 153 may output the determination result DI based on the comparison result received from the comparator 152. In an embodiment, when the comparison result received from the comparator 152 is less than a specific size, the determiner 153 may determine that the battery module 140-1 is in a normal state and may output the result as a first determination result. In an embodiment, when the comparison result received from the comparator 152 is greater than or equal to the specific size, the determiner 153 may determine that the battery module 140-1 is in an abnormal state and may output the result as a second determination result.

The determination result DI output from the determiner 153 may be provided to the controller 110. The controller 110 may control the row selection signal and/or the output selection signal CEN based on the determination result DI.

When the first row selection signal RSS1 is activated, the first determination module 150-1 and the second determination module 150-2 may receive the first output signal and the second output signal from the first control circuits 120-1, respectively. The determination modules may determine whether the first and second battery modules 140-1 and 140-2 in the first row R1 are in the normal state based on the received output signal.

In an embodiment, when the first and second battery modules 140-1 and 140-2 are determined to be normal, all of the determination modules may output the result as the first determination result. When the first determination result is received from all the determination modules, the controller 110 may activate the second row selection signal RSS2 to determine whether the third battery module 140-3 and the fourth battery module 140-4 in the second row R2 are normal.

In an embodiment, when the first battery module 140-1 and/or the second battery module 140-2 are determined to be abnormal, the determination module connected thereto may output the second determination result. For example, when the first battery module 140-1 is abnormal and the second battery module 140-2 is normal, the first determination module 150-1 may output the second determination result and the second determination module 150-2 may output the first determination result.

When the second determination result is received from the determination modules, the controller 110 may provide the output selection signal CEN of the first signal to a control circuit connected to the battery module having an abnormal state. Accordingly, balancing may be performed on the battery module having the abnormal state. Thereafter, the controller 110 may activate the second row selection signal RSS2 to determine whether the third battery module 140-3 and the fourth battery module 140-4 in the second row R2 are normal.

Determining whether the battery modules of the battery pack block 140 are normal and performing of the balancing may be sequentially performed with respect to a plurality of rows.

The battery balancing system according to the present disclosure may simultaneously determine states of battery modules disposed in parallel in the same row and may perform the balancing. Accordingly, a balancing time for the battery modules included in the battery pack block 140 may be reduced and efficiency may be improved.

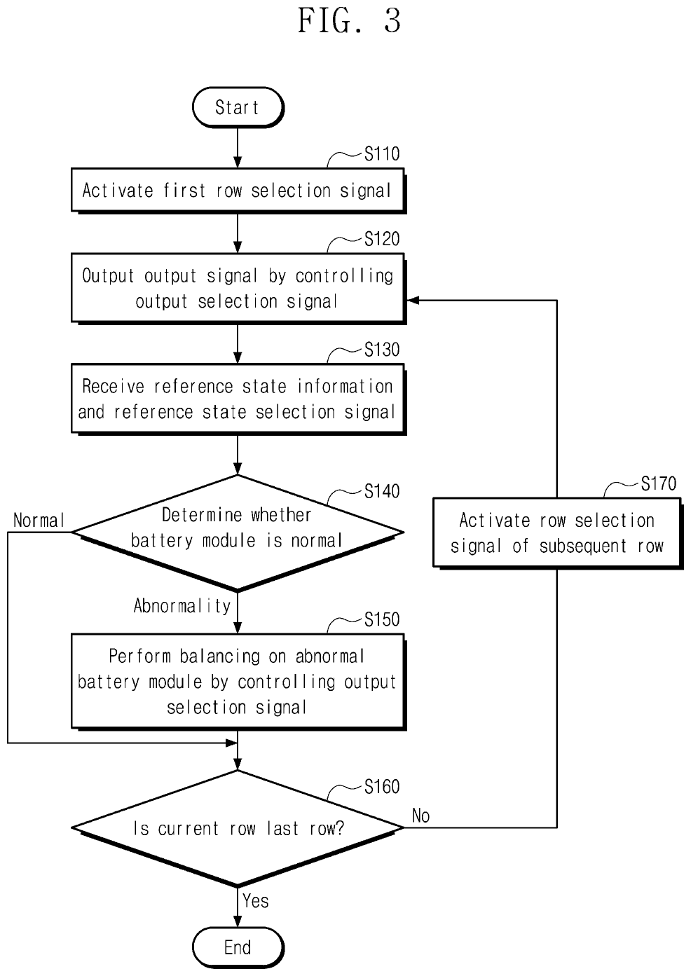

FIG. 3 is a flowchart illustrating an operation method of a battery balancing system of FIG. 1. Hereinafter, the operation of the battery balancing system will be described in detail with reference to FIG. 1.

Referring to FIGS. 1, 2 and 3, in operation S110, the controller 110 may activate a first row selection signal and may inactivate other row selection signals. When the first row selection signal is activated, switches SWT of the first control circuits 120-1 to which the first row selection signal is applied may be switched on.

In operation S120, the controller 110 may control the output selection signal CEN to provide the output selection signal CEN of the second signal to the first control circuits 120-1 of the first row R1. Accordingly, the first control circuits 120-1 may output the outputs of the battery modules in the first row R1 as output signals.

In operation S130, the controller 110 may provide the reference state information and the reference state selection signal BEN to the determination modules. The determination module may receive the reference state selection signal BEN and the reference state information. The comparator of the determination module may receive the reference state information and an output signal selected based on the reference state selection signal BEN.

In operation S140, each determination module may determine whether the battery module is normal by comparing the output signal with the reference state information. When the battery module is determined to be normal, the determination module may output the first determination result. When the battery module is determined to be abnormal, the determination module may output the second determination result.

When all of the determination modules output the first determination result, operation S160 may be performed. When at least one of the determination modules outputs the second determination result, operations S150 and S160 may be performed.

In operation S150, the controller 110 may provide the output selection signal CEN of the first signal to the control circuit connected to the determination module that outputs the second determination result. The control circuit receiving the first signal may perform balancing of the battery module by inputting the output of the battery module to the balancing module. After balancing of the battery module is completed, operation S160 may be performed.

In operation S160, the controller 110 may determine whether the current row in which the row selection signal is activated is the last row. When the next row exists, operation S170 may be performed. When the current row is the last row, the controller 110 may end the operation.

In operation S170, the controller 110 may activate the subsequent row selection signal and may inactivate other row selection signals. Thereafter, operations S120 to S160 are repeated to perform the balancing operation on the subsequent row for which the row selection signal is active.

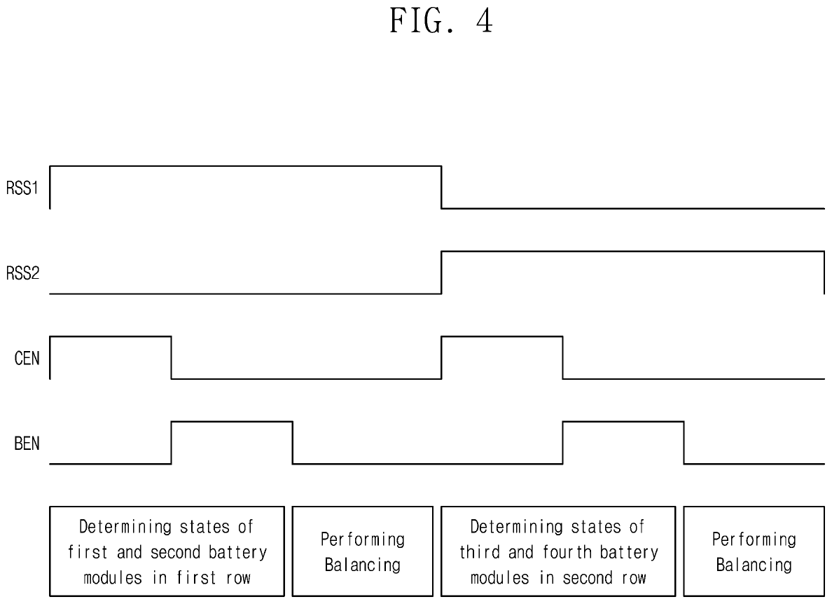

FIG. 4 is a timing diagram for describing an operation of a battery balancing system of FIG. 1. Hereinafter, with reference to FIG. 2, a method of operating the balancing system according to the present disclosure will be described.

Referring to FIGS. 2 and 4, the first row selection signal RSS1 may be activated first. The output selection signal of ‘1’ may be provided to the first control circuits in the first row. Accordingly, the outputs of the first battery module and the second battery module may be transferred to the first determination module 150-1 and the second determination module 150-2 through the first output line and the second output line.

In a state where the first row selection signal RSS1 is activated, a reference selection signal may be provided to the first determination module 150-1 and the second determination module 150-2. Accordingly, state determination of the first and second battery modules in the first row may be performed. The first determination module 150-1 may determine the state of the first battery module, and the second determination module 150-2 may determine the state of the second battery module.

As a result of the state determination, balancing may be performed when any one of the first and second battery modules is abnormal. In this case, the ‘0’ signal may be provided to the first control circuit as the output selection signal.

As a result of state determination, when both the first and second battery modules are in a normal state or after balancing is performed, the first row selection signal RSS1 may be inactivated and the second row selection signal RSS2 may be activated. Accordingly, state determination and balancing of the third and fourth battery modules in the second row may be performed.

According to an embodiment of the present disclosure, a battery balancing system capable of reducing the time required to perform battery balancing is provided.

The above description refers to embodiments for implementing the present disclosure. Embodiments in which a design is changed simply or which are easily changed may be included in the present disclosure as well as an embodiment described above. In addition, technologies that are easily changed and implemented by using the above embodiments may be included in the present disclosure. While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A battery balancing system comprising:
a battery pack block including a first battery module and a second battery module arranged in a first row and a third battery module and a fourth battery module arranged in a second row;
a balancing control block including first control circuits respectively connected to the first battery module and the second battery module in the first row and second control circuits respectively connected to the third battery module and the fourth battery module in the second row;
a battery state determination block configured to receive output signals from the first control circuits and the second control circuits to determine states of the first to fourth battery modules; and
a controller configured to apply a first row selection signal to the first control circuits and to apply a second row selection signal to the second control circuits, and
wherein, when the first row selection signal is activated, the battery state determination block determines states of the first and second battery modules in the first row and outputs a determination result, and
wherein the controller is configured to perform balancing with respect to the first and second battery modules of the first row or to activate the second row selection signal, based on the determination result.

2. The battery balancing system of claim 1, further comprising:
a balancing block including balancing modules respectively connected to the first control circuits and the second control circuits, and
wherein each of the first control circuits and the second control circuits is configured to connect a battery module and a balancing module connected thereto or to output an output of the battery module as the output signal, based on an output selection signal, and
wherein the controller is configured to control the output selection signal based on the determination result.

3. The battery balancing system of claim 2, wherein each of the first control circuits includes:
a multiplexer configured to output an output of the battery module connected to the first control circuit as a first output or a second output based on the output selection signal; and
a switch including a first gate terminal to which the first row selection signal is applied, a first source/drain connected to the second output, and a second source/drain to output the output signal, and
wherein the first output is connected to the balancing module connected to the first control circuit.

4. The battery balancing system of claim 3, wherein the controller is configured to:
when the determination result is abnormal, perform balancing with respect to an abnormal battery module by outputting an output of the abnormal battery module as the first output, by controlling the output selection signal; and
when the determination result is normal, deactivate the first row selection signal and activate the second row selection signal.

5. The battery balancing system of claim 1, wherein the first battery module and the third battery module are arranged in a first column, and the second battery module and the fourth battery module are arranged in a second column,
the first control circuit connected to the first battery module and the second control circuit connected to the third battery module transfer the output signal through a first output line corresponding to the first column,
the first control circuit connected to the second battery module and the second control circuit connected to the fourth battery module transfer the output signal through a second output line corresponding to the second column, and
the battery state determination block includes a first determination block connected to the first output line and a second determination block connected to the second output line.

6. The battery balancing system of claim 5, wherein the first determination block is configured to compare an output signal received through the first output line with reference state information to determine a state of the first battery module in the first column and to output the determination result, and
wherein the second determination block is configured to compare an output signal received through the second output line with reference state information to determine a state of the second battery module in the second column and to output the determination result.

7. The battery balancing system of claim 6, wherein, when at least one of the first determination block and the second determination block outputs the determination result determined to be the abnormal, the controller is configured to perform balancing with respect to the battery module determined to be the abnormal among the first battery module and the second battery module, and
wherein, when both the first determination block and the second determination block output the determination result determined to be the normal, the controller is configured to activate the second row selection signal.

8. The battery balancing system of claim 6, wherein the first determination block includes:
a multiplexer configured to select and output the reference state information;
a comparator configured to compare the output signal received through the first output line with the selected reference state information to generate a comparison result; and
a determination unit configured to determine the state of the first battery module based on the comparison result to output the determination result.

9. The battery balancing system of claim 8, wherein the reference state information includes a reference voltage, a reference current, and a reference temperature, and
the multiplexer is configured to select and output any one of the reference voltage, the reference current, and the reference temperature based on a reference state selection signal.

10. The battery balancing system of claim 5, further comprising:
a balancing block including balancing modules respectively connected to the first control circuits and the second control circuits, and
wherein each of the first control circuits and the second control circuits is configured to connect a battery module and a balancing module connected thereto or to output an output of the battery module as the output signal, based on an output selection signal, and
wherein the controller is configured to generate the output selection signal based on the determination result.

11. A method of operating a battery balancing system including a first battery module and a second battery module arranged in a first row and respectively connected to first control circuits, and a third battery module and a fourth battery module arranged in a second row and respectively connected to second control circuits, the method comprising:
activating a first row selection signal applied to the first control circuits;
receiving output signals of the first and second battery modules from the first control circuits;
comparing the output signal with reference state information to determine whether the first and second battery modules are normal and outputting a determination result; and
performing balancing with respect to the first and second battery modules based on the determination result or activating a second row selection signal applied to the second control circuits.

12. The method of claim 11, wherein the first control circuits and the second control circuits respectively connect a battery module and a balancing module connected thereto or respectively output an output of the battery module as the output signal, based on an output selection signal.

13. The method of claim 12, wherein each of the first control circuits includes:
a multiplexer configured to output an output of the battery module connected to the first control circuit as a first output or a second output based on the output selection signal; and
a switch including a first gate terminal to which the first row selection signal is applied, a first source/drain connected to the second output, and a second source/drain to output the output signal, and
wherein the first output is connected to the balancing module connected to the first control circuit.

14. The method of claim 13, wherein, when the determination result is abnormal, balancing with respect to an abnormal battery module is performed by outputting an output of the abnormal battery module as the first output, by controlling the output selection signal, and
wherein, when the determination result is normal, the first row selection signal is deactivated and the second row selection signal is activated.

15. The method of claim 11, wherein, receiving the output signal comprises:
receiving the output signal through a first output line from a first control circuit connected to the first battery module arranged in a first column; and
receiving the output signal through a second output line from a first control circuit connected to the first battery module arranged in a second column.

16. The method of claim 15, wherein the outputting of the determination result includes:
outputting the determination result by comparing an output signal received through the first output line with the reference state information to determine a state of the first battery module in the first column; and
outputting the determination result comparing an output signal received through the second output line with the reference state information to determine a state of the second battery module in the second column.

17. The method of claim 16, further includes:
balancing, when at least one of the first battery module and the second battery module is determined to be abnormal, with respect to the battery module determined to be the abnormal among the first battery module and the second battery module, and
activating the second row selection signal, when both the first battery module and the second battery module are determined to be normal.

18. The method of claim 16, wherein the outputting of the determination result includes outputting the determination result from a first determination block connected to the first output line, and
wherein the first determination block includes:
a multiplexer configured to select and output the reference state information;
a comparator configured to compare the output signal received through the first output line with the selected reference state information to generate a comparison result; and
a determination unit configured to determine the state of the first battery module based on the comparison result to output the determination result.

19. The method of claim 18, wherein the reference state information includes a reference voltage, a reference current, and a reference temperature, and
wherein the multiplexer selects and outputs any one of the reference voltage, the reference current, and the reference temperature based on a reference state selection signal.
